(19) United States
(12) Patent Application Publication
(10) Pub. No.: US 2013/0162260 A1
(43) Pub. Date: Jun. 27, 2013

(54) METHOD AND CELL MONITORING UNIT FOR MONITORING A RECHARGEABLE BATTERY

(71) Applicant: Axel Krause, Nesslau (CH)

(72) Inventor: Axel Krause, Nesslau (CH)

(73) Assignee: BRUSA ELEKTRONIK AG, Sennwald (CH)

(21) Appl. No.: 13/817,444

(22) PCT Filed: Aug. 19, 2011
(86) PCT No.: PCT/IB11/53656

§ 371 Date: Feb. 21, 2013

Related U.S. Application Data
(63) Continuation-in-part of application No. PCT/IB11/51929, filed on May 2, 2011.
(60) Provisional application No. 61/380,689, filed on Sep. 7, 2010.
(60) Provisional application No. 61/332,725, filed on May 7, 2010.

(30) Foreign Application Priority Data
May 7, 2010 (EP) 10162353
Sep. 7, 2010 (EP) 10175670

(51) Int. Cl. G01R 31/36

(52) U.S. Cl. CPC G01R 31/3606
USPC 324/433; 324/434

(57) ABSTRACT

A method for monitoring a rechargeable battery (1) with multiple cells (2, 2a . . . 2n) is described, as well as a cell monitoring unit (3, 3a . . . 3n) for such, in which in a normal mode (MN) a measurement (UCa, UCb) of a parameter of a cell (2, 2a . . . 2n) is determined using a reference value (URa, URb) provided for each cell (2, 2a . . . 2n). In addition, in a test mode (MT) the reference values (URa, URb) of adjacent cells (URb) used for determining measurements (UCa, UCb) of the parameter in question and provided for each cell (2, 2a . . . 2n) are compared with each other in a periodically recurring manner. An error signal is issued if the comparison result exceeds a predefinable limit value.

This application is a 35 U.S.C. 371 national-phase entry of PCT International application no. PCT/IB2011/053656 filed on Aug. 19, 2011 and also claims benefit of priority as a non-provisional of prior U.S. provisional application No. 61/380,689 filed on Sep. 7, 2010, and also claims benefit of priority to prior European application no. EP10175670 filed on Sep. 7, 2010, and the present application also claims benefit as a continuation-in-part of prior PCT International application no. PCT/IB2011/051929 filed on May 2, 2011 that designated the United States and was published as WO 2011/138726A2 in English, which PCT International application no. PCT/IB2011/051929 in-turn claims benefit of priority as a non-provisional of prior U.S. provisional application No. 61/332,725 filed on May 7, 2010, and also claims benefit of priority to prior European application no. EP10162353 filed on May 7, 2010, and the respective entireties of European application no. EP10175670, of U.S. provisional application No. 61/380,689, of U.S. provisional application No. 61/332,725, of European application no. EP10162353, of parent PCT International application no. PCT/IB2011/053656, as well as of parent PCT International application no. PCT/IB2011/051929 are all expressly incorporated herein by reference in their entireties, for all intents and purposes, all as if identically set forth in full herein.

The invention relates to a method for monitoring a rechargeable battery with multiple cells, in which in a normal mode a measurement value of a parameter of a cell is determined using a reference value that is provided per cell. The invention additionally relates to a cell monitoring unit for monitoring a cell of a rechargeable battery, comprising a reference source for specifying a reference value and a measurement device for measuring a deviation of a parameter of a cell from the reference value.

Rechargeable batteries form the energy supply of the overwhelming majority of electrically operated mobile devices. In order to attain a required nominal voltage, a required current and/or required capacity, for the most part multiple galvanic cells are assembled to form a rechargeable battery.

With lithium-ion batteries and lithium-polymer batteries in particular it has been shown that the individual cells reach different voltage levels during the discharging process, or during charging of multiple series-connected cells in the absence of further measures they reach different charge states. In order to avoid overcharging or deep discharging, both of which are damaging to the cell, and also to optimally exploit the capacity of the battery, the cells are individually checked during charging. For this purpose, in multi-cell rechargeable batteries separate contacts are provided for each cell, which allow the individual charging or discharging of an individual cell. The equalisation of these different cell voltages or charge states is also known as “balancing”.

For this purpose a cell monitoring unit is frequently assigned to each cell of a rechargeable battery, controls the charge state, the charging and the discharging of a cell. In some cases this cell monitoring unit frequently determines the cell voltage and/or the cell temperature. Most frequently, a cell monitoring unit communicates with a central monitoring unit assigned to the entire battery, which collects the data from all cell monitoring units and controls these accordingly. The central monitoring unit usually also communicates with a central vehicle control unit, which for example informs the driver for which routes the battery still has enough charge. Naturally, parameters other than the cell voltage and the cell temperature can be determined or regulated.

To ensure correct measurements, reference sources, for example reference voltage sources, reference temperature sources or reference sources representing a temperature are provided. for example such a reference source can be provided in a central monitoring unit and/or in a cell monitoring unit. An example for such an arrangement is disclosed in EP 0 814 556 A2, which shows a method for balancing charges of a plurality of batteries coupled in series. The method includes determining actual or estimated rates of self-discharge of the batteries and individually shunting across one or more of the batteries to cause shunt currents which at least partially compensate for differences in the rates of self-discharge between batteries. To obtain a reference voltage for comparison with the actual cell voltage, a voltage regulator is provided for each cell.

Furthermore, US 2006/0028179A1 discloses an abnormal voltage detector apparatus for an assembled battery including a plurality of battery blocks connected in series to each other. In the abnormal voltage detector apparatus, a detecting part detects whether or not each of the battery blocks is in a voltage abnormality state by comparing either one of a voltage of each battery block and each battery measuring voltage, that is a voltage lowered from the voltage of each battery block, with a predetermined reference voltage. For generation of the reference voltage, a number of Zener-diodes is provided.

Since these reference sources very often have long-term drifts, a balancing of these is required. For example, a cell monitoring unit can have two reference sources which are compared with each other at regular intervals. If an excessive deviation of the two reference sources is found, which should nominally deliver the same value for the reference parameter, then an error signal is triggered. Achieving this requires a relatively high circuit complexity in the cell monitoring units.

In order to keep the complexity in the cell monitoring units down, a reference source can also be provided only in the central monitoring unit. This does indeed reduce the circuit complexity in the cell monitoring units, however in doing so drastically increases the data traffic between the cell monitoring units and the central monitoring unit, since for every measurement the central reference source must be polled. In addition, between the cell monitoring units and the central monitoring units there are often long cable leads present, which means that relatively large measurement errors result, due to the resistive losses in the cable leads and due to induced voltages as a result of external electromagnetic fields, such as occur e.g. near to electric motors for electrically powered vehicles.

As a compromise between the two approaches mentioned above, as it is well known by a person skilled in the art, in each cell monitoring unit a single reference source is often provided, which is balanced at regular intervals with a reference source arranged in the central monitoring unit. This indeed reduces the data traffic mentioned, but the measurement errors mentioned due to resistive losses and induced voltages are not thereby prevented.

The object of the invention therefore is to provide an improved method and an improved cell monitoring unit for monitoring a rechargeable battery. In particular, an aim is to simplify the balancing of reference sources, but without increasing the data traffic between the cell monitoring units and a central monitoring unit and without having to incur measurement errors due to long cables between the units being addressed.

According to the invention this object is achieved by a method of the type initially described, in which

the reference values of adjacent cells used for determining measurements of the said parameter and provided for each cell are compared with each other on a periodically recurring basis, and

an error signal is issued when the comparison result exceeds a predefinable limit value.

The object of the invention is furthermore achieved by a cell monitoring unit of the type initially described, comprising

means for periodically recurring comparison of the said reference value with a reference value of an adjacent cell monitoring unit and

means for issuing an error signal, when the comparison result exceeds a predefinable limit value.

By means of the invention the disadvantages of the prior art mentioned above can be successfully overcome. On the one hand, for the balancing of the reference values no data need to be exchanged between the cell monitoring units and a central monitoring unit. Moreover, measurement errors due to long cables between the individual reference sources are minimised.

“Adjacent” in the context of the invention does not necessarily mean physically adjacent, but “electrically” adjacent. For example, two cells electrically connected together are “electrically” adjacent, but need not be arranged in direct physical proximity, albeit this is advantageous due to the error susceptibility of long leads.

Advantageous configurations and extensions of the invention either follow from the description when viewed together with the figures, or are disclosed by them.

It is convenient if in the normal mode:

the deviation of the measurement from the reference value of the cell being measured is integrated over a first time period and

the reference value of the measured cell is integrated over a second time period,

wherein the respective start values and end values of the integration cover the same range.

In this manner, if the first and the second time period and the reference value are known, it is simple to determine the measurement required.

It is further convenient if in the normal mode:

the deviation of the measurement from the reference value of the measured cell is integrated over a first time period and starting at a first starting value

the reference value of the measured cell is integrated over a second time period until the first starting value is reached again,

wherein the difference between the measured value and a reference value of an adjacent cell is taken as a first starting value.

In this way the cell monitoring unit according to the invention can be configured particularly simply, since the said difference can be formed easily with analogue components, in particular with an operational amplifier.

It is advantageous when the first time period is dimensioned such that the starting value of the integration is always non-zero. This means it can be guaranteed that the measurement result is not corrupted as a result of assuming that the integration is taking place during the first time period, although the integration (unnoticed) has stopped at the value zero. When using analogue integrators their saturation values should normally be taken into account, correspondingly with digital integrators an overflow of the digital values.

It is convenient if in test mode the reference value of the measured cell is integrated over a second time period starting from a known second starting value, until the first starting value has again been reached. In this way, after completion of the test mode the integrator is again in the initial state for the normal mode.

It is advantageous if the value zero is provided as a second starting value. In this way the integrator can simply be reset for preparing the test mode, or the integration is performed over a sufficiently long time period, so that the value zero is certain to be reached.

It is additionally particularly advantageous if in the normal mode:

the deviation of the measurement from the reference value of the measured cell is integrated over a first time period and starting at a first initial value

the reference value of the measured cell is integrated over a second time period until the first starting value has again been reached,

wherein as a first starting value the difference between the measurement and a reference value of an adjacent cell is taken and the first time period is dimensioned such that the starting point of the integration is always non-zero, and if in the test mode

the reference value of the measured cell is integrated over a second time period starting from a known second starting value, until the first starting value has again been reached, wherein the value zero is provided as a second starting value, and

the second starting value is obtained by prior integration with the deviation of the measurement from the reference value of the measured cell over a first time period, and starting from the first starting value by selection of a sufficiently large first time period or by resetting the integration.

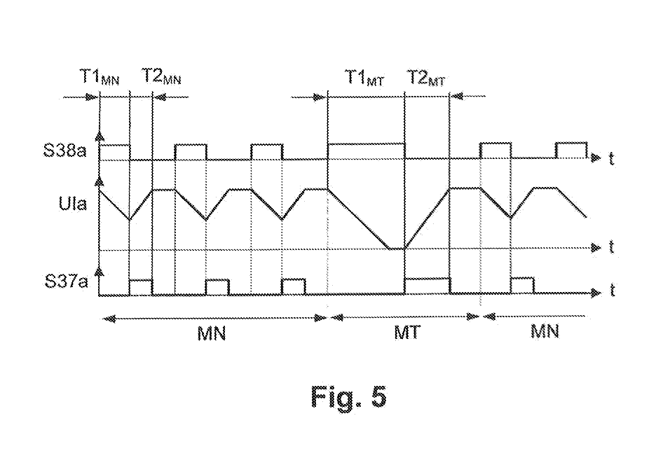

In this embodiment, the advantages of the previously cited variants of the invention are combined, which means that a particularly advantageous configuration of the invention results (on this point, see in particular also the waveform of the starting value of the integrators in FIG. 5).

It is moreover particularly advantageous if the measurement value of the said parameter of a cell in the normal mode is determined using the relation

$$T {2}_{MN} = T {1}_{MN} \cdot ( \frac{UCa}{URa} - 1 )$$

In this way, by measuring the integration time, which can be easily determined with a timer component or a microcontroller, the required measurement can easily be obtained.

It is also particularly advantageous if the comparison of the said reference values of adjacent cells in the test mode is carried out using the relation

$$T {2}_{MT} \approx T {2}_{MN} \cdot \frac{{R}_{31} {C}_{32}}{T {1}_{MT}}$$

In this way, by measuring the integration time, which can be easily determined with a timer component or a microcontroller, it can be easily tested whether the reference sources are (still) balanced.

It is convenient for forming the reference value if a reference voltage source is provided. The voltage of a cell of a rechargeable battery can be simply and accurately measured in this way.

It is furthermore convenient for forming the reference value if a reference temperature source, or a reference source representing this temperature, is provided. The temperature of a cell of a rechargeable battery can be simply and accurately measured in this way. A reference source representing the temperature can be designed as a temperature-sensitive resistor, for example.

It is also particularly convenient if the deviation of a measurement of a parameter of a cell from a reference value provided per cell is transmitted as a pulse-width modulated signal to a central monitoring unit. In this way, measurements can be transmitted rapidly and securely from the cell monitoring units to the central monitoring unit.

It is finally particularly advantageous if the reference values provided per cell are compared with a central reference value provided in a central monitoring unit in a periodically recurring manner. In this way, the certainty that the reference sources in the cell monitoring units are delivering a correct value can be increased, or all reference sources in the cell monitoring units can be balanced from time to time in such a manner that they deliver the same value as the central reference source in the central monitoring unit.

At this point it is noted out that the variants to the method according to the invention cited and the advantages resulting therefrom, apply in equal measure to the cell monitoring unit according to the invention and vice versa.

It is noted finally that the method according to the invention or the cell monitoring unit according to the invention can be implemented in software and/or in hardware. If the invention is implemented in software, then a program which runs in a microprocessor or micro-controller executes the steps according to the invention. Naturally the invention can also be implemented purely in hardware, for example with an ASIC (Application Specific Integrated Circuit). The latter can also include a processor however. Finally, one part of the invention can be implemented in software, and another part in hardware.

The above configurations and extensions of the invention can be combined in any desired manner.

The present will now be described in more detail with the aid of the exemplary embodiments given in the schematic Figures of the drawings. In these:

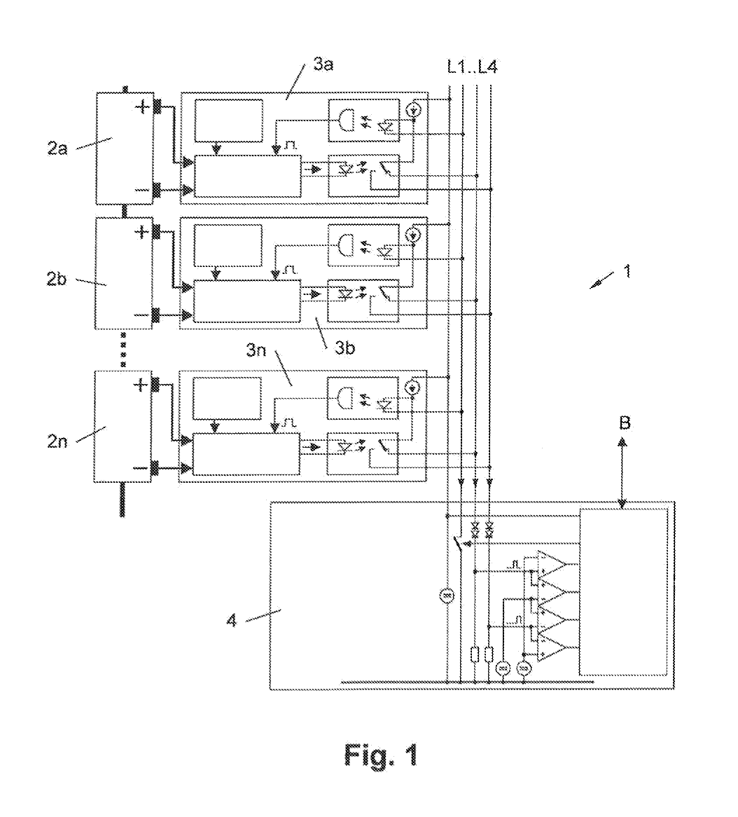

FIG. 1 shows schematically an overview drawing of a rechargeable battery with a cell monitoring unit and a central monitoring unit;

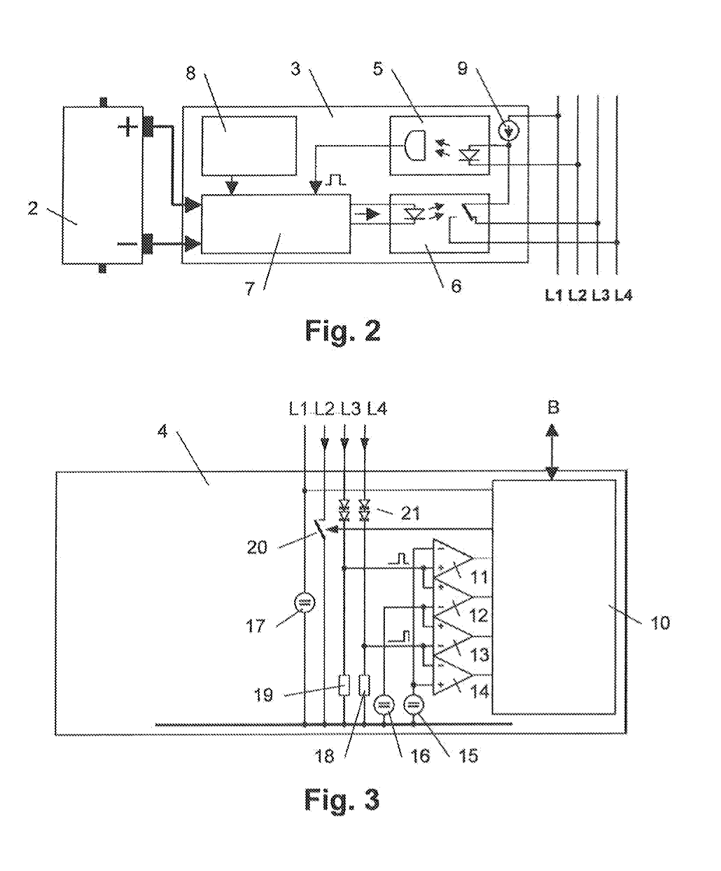

FIG. 2 shows a detail view of a cell monitoring unit;

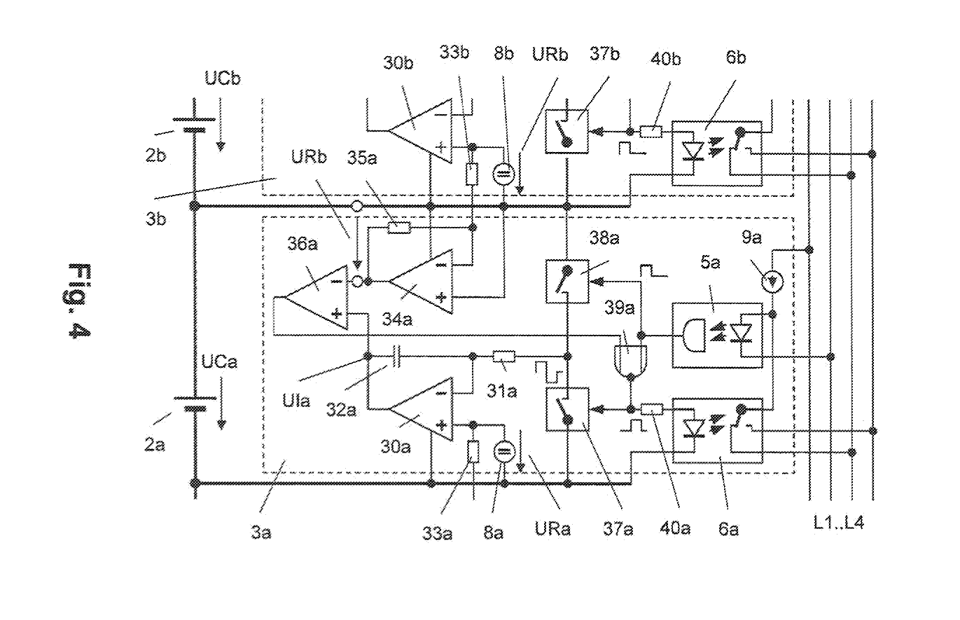

FIG. 3 shows a detail view of a central monitoring unit;

FIG. 4 shows an example circuit for monitoring a reference source of a cell monitoring unit and

FIG. 5 shows the time curves of various signals arising in the circuit according to FIG. 4.

In the Figures of the drawing, equivalent and similar parts are assigned identical reference labels and functionally similar elements and features - except where otherwise indicated - are assigned identical reference labels but with different indices.

FIG. 1 shows a battery 1, comprising multiple cells 1a . . . 2n with similarly constructed cell units 3a . . . 3n connected thereto and a central monitoring unit 4. The cell monitoring units 3a . . . 3n are connected via signal leads L1 . . . L4 to the central monitoring unit 4. The central monitoring unit 4 is finally connected via a data bus B to further control units, not shown.

FIG. 2 shows a cell monitoring unit 3 from FIG. 1, which is connected to a cell 2, in detail. The cell monitoring unit 3 comprises an input-side opto-coupler 5 and an output-side opto-coupler 6. These are indeed advantageous but by no means essential, since the connection of the cell monitoring unit 3 to the signal leads L1 . . . L4 can also be effected in a different way, for example via isolating transformers. The cell monitoring unit 3 further comprises a measurement converter 7 and a reference source 8. The measurement converter 7 is connected to the input-side opto-coupler 5, the output-side opto-coupler 6 and the reference source 8. Finally, on the input-side a current source 9 is also arranged.

FIG. 3 now shows the central monitoring unit 4 from FIG. 1 in detail. This comprises a microcontroller 10, multiple comparators 11 . . . 14, three voltage sources 15 . . . 17, two resistors 18, 19, a switch 20 and diodes 21.

The function of the rechargeable battery 1 according to the invention is now explained in further detail using FIGS. 1 to 3:

Via the second signal lead L2 a reference pulse sequence with a defined pulse length (e.g. 0.5 ms) and defined frequency (e.g. 1 kHz) is sent from the central monitoring unit 4 to all cell monitoring units 3a . . . 3n. To this end, the switch 20 of the microcontroller 10 is periodically driven in a corresponding way. When the switch 20 is closed the electrical circuit between the voltage source 17, the current sources 9, the opto-couplers 5 and the ground connection is closed. In this way, the signal applied to the switch 20 is sent to the cell monitoring units 3a . . . 3n and is used there as a reference pulse for the measurement converter 7.

Using the reference source 8 and the reference pulse, each cell monitoring unit 3a . . . 3n generates a measurement pulse synchronous with the reference pulse, the duration of which is linearly related to the measurement. In the present example the cell voltage is provided as a measurement parameter and correspondingly, a reference voltage source as a reference source 8. Analogously, the cell temperature for example could be provided as a measurement value, and a reference temperature source as a reference source 8. Often a temperature from a temperature sensor is converted into a resistance value or a voltage. The reference source 8 can then accordingly be provided by a reference resistance or, in turn a reference voltage source or a reference current source.

By means of the measurement converter 7 in the present example a pulse-width modulated signal (PWM signal) is generated from a voltage signal. For example, a rising/falling edge of a periodic signal with constant frequency is shifted by 0.25 ms for each Volt by which the measurement deviates from a reference value of 2V. The quantity taken as the measurement therefore is the deviation of a cell parameter from a reference value provided for each cell. This measurement pulse occurs primarily in the gap between two reference pulses.

By means of the output-side opto-coupler 6, the first lead L1 is then connected to the third lead L3 or the first lead L1 to the fourth lead L4. Due to the current source 9 across the resistors 18 and 19 a voltage signal is generated in the central monitoring unit 4. If multiple opto-couplers 6 are activated at the same time, then the current sources 9 are connected in parallel and thus generate a summed current, which is expressed in an increased voltage value at the resistors 18 and 19. In general the voltages of the cells 1a . . . 2n are different, so that the opto-couplers 6, due to the respective individual PWM signal, are activated at different times. The addition of the PWM signal therefore results in a staircase-shaped summed signal.

At this point it is noted that the sub-division into different units shown in FIGS. 1 to 2 is not necessarily physically realised in the form shown. Of course, multiple functional blocks can be combined in one component. For example, the cell monitoring unit 3 may in essence be assembled from a single component, for example from a micro-controller, in which the individual functional blocks are formed by circuit parts of the micro-controller and/or appropriate software routines. An implementation in the form of an ASIC (Application Specific Integrated Circuit) is also possible.

FIG. 4 shows a special embodiment of a cell monitoring unit 3a, which is suitable for embodying the method according to the invention. Here, a cell monitoring unit 3a and in sections, a cell monitoring unit 3b (here not as in FIG. 1 below but above) are shown. Specifically, FIG. 4 shows units which are provided for balancing a reference value, here a reference voltage. The units shown in the previous Figures in a cell monitoring unit 3a . . . 3n can of course be additionally present in a real embodiment of a cell monitoring unit 3a . . 3n. This means, a cell monitoring unit 3 can contain all the units shown in FIG. 2.

The cell monitoring unit 3a comprises an input-side opto-coupler 5a, an output-side opto-coupler 6a, a reference source 8a (in the present case designed as a reference voltage source) and a current source 9a. In addition the cell monitoring unit 3a comprises an operational amplifier 30a, to the positive input of which the reference voltage source 8a is connected, and which with the resistor 31a and the capacitor 32a forms an integrator. To the positive input of the operational amplifier 30a, in addition, a resistor 33a is connected which is provided for connecting to another cell monitoring unit. In addition the cell monitoring unit 3a comprises an operational amplifier 34a, the positive input of which is connected to the plus pole of the cell 2a, and which together with the resistors 35a and 33b forms a summing amplifier. The outputs of the operational amplifier 30a and 34a are connected to a comparator 36a. The cell monitoring unit 3a also comprises a switch 37a, with which the input of the integrator can be switched to the minus pole of the cell 2a, and a switch 38a, with which the input of the integrator can be switched to the plus pole of the cell 2a. In addition, the cell monitoring unit 3a comprises a NOR-gate 39a, to the inputs of which the output of the input-side opto-coupler 5a and the output of the comparator 36a are fed. The output of the NOR-gate 39a is fed to the control input of the switch 37a and via a resistor 40a to the input of the output-side opto-coupler 6a.

The functioning of the circuit shown in FIG. 4 will now be described in more detail with the aid of FIG. 5, which shows the temporal waveforms of the input signal S37a of the switch 37a, the input signal S38a of the switch 38a, and the output voltage of the integrator Ula. A distinction is made here between a normal mode MN and a test mode MT.

During the normal mode MN the voltage UCa-URa is negatively integrated during the reference time T1_{MN} by means of the integrator (operational amplifier 30a) (see also FIG. 5). During this process the switch 38a is closed, the switch 37a open. After the reference time T1_{MN} has elapsed the output-side opto-coupler 6a is switched over and the reference voltage URa is positively integrated over the period T2_{MN} (see FIG. 5 also), until the comparator threshold UCa-URb is reached. During this period the switch 38a is open, the switch 37a closed. The integration is then stopped and the starting signal Ula again becomes inactive. Thus the comparator threshold is again the start value for the next integration.

The difference in the starting voltage Ula at the output of the integrator at two different times is given quite generally by:

$$Δ U = UE \cdot t \cdot \frac{1}{{R}_{31} {C}_{32}}$$

In the concrete case this means

$$Δ U = ( UCa - URa ) \cdot T {1}_{MN} \cdot \frac{1}{{R}_{31} {C}_{32}}$$

$$and$$

$$Δ U = URa \cdot T {2}_{MN} \cdot \frac{1}{{R}_{31} {C}_{32}}$$

From this it follows that

$$( UCa - URa ) \cdot T {1}_{MN} \cdot \frac{1}{{R}_{31} {C}_{32}} = URa \cdot T {2}_{MN} \cdot \frac{1}{{R}_{31} {C}_{32}}$$

$$T {2}_{MN} = T {1}_{MN} \cdot ( \frac{UCa}{URa} - 1 )$$

As can be easily seen, the reference voltage URb does not enter into the starting pulse length T2_{MN}. Also, this does not depend on the value of the resistor 31 or the capacity of the capacitor 32.

During the test mode MT the voltage UCa-URa is in turn negatively integrated by means of the integrator during the reference time T1_{MT}. During this process the switch 38a is again closed, the switch 37a open. This time T1_{MT} is chosen such that the output of the operational amplifier 30a is also certain to reach zero at a minimal cell voltage and to remain there. After the reference time T1_{MT} has elapsed the output-side opto-coupler 6a is switched over and the reference voltage URa is positively integrated over the period T2_{MT}, until the comparator threshold UCa-URb is reached again. During this period the switch 38a is open, the switch 37a closed. The integration is then stopped and the starting signal Ula again becomes inactive. The following applies:

$$Δ U = ( UCa - URb ) = URa \cdot T {2}_{MT} \cdot \frac{1}{{R}_{31} {C}_{32}}$$

From this it follows that

$$T {2}_{MT} = {R}_{31} {C}_{32} \cdot ( \frac{UCa}{URa} - \frac{URb}{URa} )$$

The time T2_{MT} now no longer depends on T1_{MT}, but on the value of the resistor 31, the capacitance of the capacitor 32 and the reference voltage URb. If now URa-URb, then we get

$$T {2}_{MT} \approx {R}_{31} {C}_{32} \cdot ( \frac{UCa}{URa} - 1 )$$

and due to

$$\frac{T {2}_{MN}}{T {1}_{MN}} = ( \frac{UCa}{URa} - 1 )$$

$$T {2}_{MT} \approx \frac{T {2}_{MN}}{T {1}_{MN}} \cdot {R}_{31} {C}_{32}$$

as long as UCa has not, or not substantially, changed. This can be assumed however, as the temporal distances between the measurements are short and a rechargeable battery cell can be neither substantially charged up or discharged in this short time. In order to increase the accuracy of the method, it can also be provided that the measurements are carried out at times of relatively low current consumption or current supply, for example when the vehicle is at a standstill, if the rechargeable battery is not charged.

Now if the resistor 31, the capacitor 32 and the measurement time T1_{MT} are known, then from the above equation a target value can be calculated for T2_{MT}. To do so, the values for the resistor 31 and the capacitor 32 can be measured and stored, for example when the circuit is first started up. A fairly large deviation of T2_{MT} from the above target value then indicates that URa or URb is no longer correct.

The analysis for this can take place directly in the central monitoring unit, because the comparator 36a does not just switch over the input voltages for the integrator, but also activates the output-side opto-coupler 6a, so that the values T2_{MN} and T2_{MT} are directly transmitted as PWM signals over the leads L3 and L4 to the central monitoring unit. If there is too great a deviation of the actual value of T2_{MT} from the target value, this can trigger an alarm or initiate other countermeasures. Here for example, a balancing of the reference voltages URa and URb with a third reference voltage would be conceivable, in order to establish which of the reference voltages URa and URb is no longer correct. As a third reference voltage, for example a central reference voltage of the central monitoring unit or a reference voltage of another cell 2, 2a . . . 2n is a possibility.

It is true that the cell monitoring unit 3a shown in FIG. 4 is very well suited to embodying the method according to the invention, however other implementations of it are also conceivable. For example, the method according to the invention may be embodied with a microprocessor or a micro-controller, which in particular performs the integrations digitally. Instead of the straight-line waveforms in FIG. 5, step-wise waveforms would then be obtained. It is also conceivable that the microprocessor or micro-controller works in combination with analogue integrators and comparators, which are formed for example using operational amplifiers. An output signal of a comparator can in this case be provided directly as a digital input signal for the microprocessor or micro-controller, an output signal of an integrator must previously be digitised by an Analogue-Digital-Converter, either integrated in the micro-controller or external.

It is further noted that while the method according to the invention is very well suited to the transmission of measurements using a pulse-width modulated signal and therefore to the devices according to FIGS. 1 to 3, it can of course also be used without these devices. For example, measurements may also be transmitted as an analogue signal or any desired digital signal.

Finally it is noted that the variants illustrated only represent a selection of the many possibilities for a method according to the invention and a cell monitoring unit 3a . . . 3n according to the invention, and may not be called upon to limit the scope of application of the invention. For the person skilled in the art it should be a simple matter, based on the considerations given here to adapted the invention to his own requirements, without departing from the scope of protection of the invention. Furthermore, it is pointed out that parts of the devices shown in the Figures can also form the basis for independent inventions.

### LIST OF REFERENCE LABELS

1 Rechargeable battery

2, 2a . . , 2n Cells

3, 3a . . . 3n Cell monitoring unit

4 Central monitoring unit

5a Input-side opto-coupler

6, 6a, 6b Output-side opto-coupler

7 Measurement converter

8, 8a, 8b Reference source

9, 9a Current source

10 Micro-controller

11 . . . 14 Comparators

15 . . . 1 7 Voltage source

18, 19 Resistors

20 Switch

21 Diodes

22 . . . 29 (not used)

30a, 30b operational amplifiers

31a Resistor

32a Capacitor

33a, 33b Resistor

34a Operational amplifier

35a Resistor

36a Comparator

37a, 37b Switches

38a Switch

39a OR-gate

40a, 40b Resistors

B Data bus

L1 . . . L4 Signal leads

MN, MT Normal mode/Test mode

T1_{MN}, T1_{MT} First time period in normal mode/test mode

T2_{MN}, T2_{MT} Second time period in normal mode/test mode

UCa, UCb Cell voltage

Ula Integrator voltage

URa, URb Reference voltage

What is claimed is:

1-14. (canceled)

15. A method of monitoring a plural-cell rechargeable battery comprising the steps of:
providing a respective reference value of a cell parameter for each respective one of the plurality of cells;
determining respectively a plurality of respective normal-mode measurements of the cell parameter in each respective one of a plurality of cells of the rechargeable battery;
in test mode comparing the respective reference values of adjacent cells in a periodically recurring manner; and,
issuing an error signal if the comparing of the reference values yields a result exceeding a predefinable limit value.

16. A method of monitoring a plural-cell rechargeable battery as claimed in claim 15 further comprising the steps of:
determining for each respective cell the respective deviation of its respective normal-mode measurement from its respective reference value, and integrating the respective deviation over a first time period;
integrating for each respective cell its respective reference value over a second time period; and,
covering the same range with respective start values and end values of the integration.

17. A method of monitoring a plural-cell rechargeable battery as claimed in claim 16 further comprising the steps of:
said integration of the respective deviation over a first time period starts from a respective first initial value;
said integration of the respective reference value over a second time period continues until the first initial value is reached again; and,
selecting the respective first initial value as the difference between a respective normal-mode measurement and a respective reference value of an adjacent cell.

18. A method of monitoring a plural-cell rechargeable battery as claimed in claim 17 further comprising the step of:
dimensioning the first time period so that the output of integration of the respective deviation always has a mathematical absolute value greater than zero.

19. A method of monitoring a plural-cell rechargeable battery as claimed in claim 17 further comprising the step of:
starting said integration of the respective reference value over a second time period from a selected second initial value.

20. A method of monitoring a plural-cell rechargeable battery as claimed in claim 19 further comprising the step of:
selecting said second initial value as zero.

21. A method of monitoring a plural-cell rechargeable battery as claimed in claim 16 further comprising the step of:
transmitting the deviation as a pulse-width-modulated signal to a central monitoring unit.

22. A method of monitoring a plural-cell rechargeable battery as claimed in claim 15 further comprising the steps of:
determining for each respective cell the respective deviation of its respective normal-mode measurement from its respective reference value, and integrating the respective deviation over a first time period that starts from a respective first initial value;
integrating for each respective cell its respective reference value over a second time period starting from a selected second initial value of zero until the respective first initial value is reached again;
covering the same range with respective start values and end values of the integration;
selecting the respective first initial value as the difference between a respective normal-mode measurement and a respective reference value of an adjacent cell;
dimensioning the respective first time period so that the respective output of integration of the respective deviation always has a mathematical absolute value greater than zero; and,
reaching the respective second initial value as a result of prior integration with the respective deviation over a sufficiently large selected first time period starting from the respective first initial value.

23. The method of monitoring a plural-cell rechargeable battery as claimed in claim 22, wherein:
said step of determining of a respective normal-mode measurement of a cell parameter in a respective cell is determined using the relation:
$$T {2}_{MN} = T {1}_{MN} \cdot ( \frac{UCa}{URa} - 1 ) .$$

24. The method of monitoring a plural-cell rechargeable battery as claimed in claim 22, wherein:
said step of comparing of the respective reference values of adjacent cells is effected using the relation:
$$T {2}_{MT} \approx \frac{T {2}_{MN}}{T {1}_{MN}} \cdot {R}_{31} {C}_{32} .$$

25. A method of monitoring a plural-cell rechargeable battery as claimed in claim 22 further comprising the step of:
transmitting the deviation as a pulse-width-modulated signal to a central monitoring unit.

26. A method of monitoring a plural-cell rechargeable battery as claimed in claim 15 further comprising the steps of:
determining for each respective cell the respective deviation of its respective normal-mode measurement from its respective reference value, and integrating the respective deviation over a first time period that starts from a respective first initial value;
integrating for each respective cell its respective reference value over a second time period starting from a selected second initial value of zero until the respective first initial value is reached again;
covering the same range with respective start values and end values of the integration;
selecting the respective first initial value as the difference between a respective normal-mode measurement and a respective reference value of an adjacent cell;
dimensioning the respective first time period so that the respective output of integration of the respective deviation always has a mathematical absolute value greater than zero;
resetting the integration to reach the respective second initial value.

27. The method of monitoring a plural-cell rechargeable battery as claimed in claim 26, wherein:
said step of determining of a respective normal-mode measurement of a cell parameter in a respective cell is determined using the relation:
$$T {2}_{MN} = T {1}_{MN} \cdot ( \frac{UCa}{URa} - 1 ) .$$

28. The method of monitoring a plural-cell rechargeable battery as claimed in claim 26, wherein:
said step of comparing of the respective reference values of adjacent cells is effected using the relation:
$$T {2}_{MT} \approx \frac{T {2}_{MN}}{T {1}_{MN}} \cdot {R}_{31} {C}_{32} .$$

29. A method of monitoring a plural-cell rechargeable battery as claimed in claim 26 further comprising the step of:
transmitting the deviation as a pulse-width-modulated signal to a central monitoring unit.

30. The method of monitoring a plural-cell rechargeable battery as claimed in claim 15, wherein:
said step of determining of a respective normal-mode measurement of a cell parameter in a respective one cell of the rechargeable battery is determined using the relation:
$$T {2}_{MN} = T {1}_{MN} \cdot ( \frac{UCa}{URa} - 1 ) .$$

31. The method of monitoring a plural-cell rechargeable battery as claimed in claim 15, wherein:
said step of comparing of the respective reference values of adjacent cells is effected using the relation:
$$T {2}_{MT} \approx \frac{T {2}_{MN}}{T {1}_{MN}} \cdot {R}_{31} {C}_{32} .$$

32. A method of monitoring a plural-cell rechargeable battery as claimed in claim 15 further comprising the step of:
in a periodically recurring manner comparing the respective reference values provided for each one of the plurality of cells with a central reference value provided in a central monitoring unit.

33. A method of monitoring a plural-cell rechargeable battery as claimed in claim 15 further comprising the step of:
forming the reference value with a reference voltage source.

34. A method of monitoring a plural-cell rechargeable battery as claimed in claim 15 further comprising the step of:
forming the reference value with a reference source that represents temperature.

31. A cell monitoring unit comprising:
a first battery cell;
a first reference source configured to provide a first reference value for said first battery cell;
a first cell measurement device configured to measure said first cell's parameter deviation from said reference value, said first measurement device being in operative communication with said reference source;
a second battery cell;
a second reference source configured to provide a second reference value for said second battery cell;
comparison circuitry connected to effect periodically recurring comparison of said first reference value and said second reference value; and,
signaling circuitry configured to produce an error signal when said recurring comparison exceeds a predefined limit, said signaling circuitry being operatively connected to receive said periodically recurring comparison effected by said comparison circuitry.
